(19) United States
(12) Patent Application Publication
(10) Pub. No.: US 2007/0001214 A1
(43) Pub. Date: Jan. 4, 2007

(54) Method of manufacturing flash memory device

(75) Inventor: Byung Soo Park, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/445,775

(22) Filed: Jun. 2, 2006

(30) Foreign Application Priority Data
Jul. 4, 2005 (KR) 2005-59868

(51) Int. Cl. H01L 21/336; H01L 29/788

(52) U.S. Cl. 257/315; 438/257

(57) ABSTRACT

A method of manufacturing flash memory devices, wherein in a peripheral region, a polysilicon layer is formed to extend on an isolation film at the interface of an active region and the isolation film. The isolation film that has been partially wet-etched is over etched when removing a dielectric layer. It is thus possible to prevent a thinning phenomenon in which a gate oxide film is made thin. As a result, a breakdown voltage of an oxide film, which occurs in the gate oxide film, can be prevented. Furthermore, characteristics of transistors can be prevented. In addition, resistance of about several hundreds ohm/square, of the polysilicon layer can be formed.

### BACKGROUND

1. Field of the Invention

The invention relates generally to a method of manufacturing semiconductor devices and, more particularly, to a method of manufacturing flash memory devices that can prevent a thinning phenomenon of a gate oxide film, which occurs in a peripheral region when a self-aligned floating gate (SAFG) is formed.

2. Discussion of Related Art

In manufacturing NAND flash memory devices, the process margin is reduced as the device is reduced in size. This causes a reduction alignment margin with a polysilicon layer used as a cell active region and a floating gate. To overcome such problem, a SAFG is applied, as described below in detail.

A sacrificial film is deposited on a semiconductor substrate in which a cell region and a peripheral region are defined. The sacrificial film and the semiconductor substrate are etched to a predetermined depth, forming a trench. An oxide film is deposited so that the trench is buried. The oxide film is polished by chemical mechanical polishing (CMP) so that a top surface of the sacrificial film is exposed.

Thereafter, the sacrificial film is stripped to form an isolation film having nipples. A gate oxide film is then formed on the entire structure. A polysilicon layer is deposited on the entire structure. The polysilicon layer undergoes CMP so that a top surface of the isolation film is exposed.

At this time, the sacrificial film is formed using a material having an etch selectivity with the oxide film when performing the polishing process after the isolation film is subsequently buried. The same process may be performed even in the peripheral region, but the dielectric layer formed in the peripheral region is stripped. A control gate is formed on the entire structure.

If the flash memory device is formed by the above-mentioned SAFG, however, a predetermined amount of the isolation film is etched during the CMP process of the polysilicon layer in a high voltage transistor formed in the peripheral region in order to control high voltage. Furthermore, when stripping the dielectric layer, a predetermined amount of the isolation film is also etched. As a result, the isolation film of the peripheral region is over etched and accordingly is formed lower than the gate oxide film. A thinning phenomenon in the gate oxide film is also generated.

If a high bias is applied to the gate, the breakdown voltage of the oxide film is generated at a portion of the gate oxide film, which is thinned due to the thinning phenomenon of the gate oxide film of the high voltage transistor. More particularly, it is further vulnerable to high voltage NMOW (HVNMOS) transistors using a voltage close to 20V or higher.

Furthermore, in a NAND flash memory device of a multi-level cell (MLC) type in which several information is stored in one cell, the thickness of the polysilicon layer low in order to reduce the interference depending on variation. In this case, the breakdown voltage of the oxide film occurs in the high voltage transistor of the peripheral region.

### SUMMARY OF THE INVENTION

In one embodiment, the invention provides a method of manufacturing flash memory devices that can prevent a thinning phenomenon of a gate oxide film, which occurs in a peripheral region, preventing the breakdown voltage of an oxide film from occurring.

A method of manufacturing a flash memory device according to an embodiment of the invention includes the steps of forming a first oxide film on a semiconductor substrate in which a peripheral region is defined, and then etching the first oxide film and the semiconductor substrate to form a trench; forming a second oxide film so that the trench is buried, forming an isolation film; forming a gate oxide film and a polysilicon layer on the resulting surface; forming a floating gate electrode by causing the polysilicon layer to have a predetermined thickness; forming a dielectric layer along the step of the floating gate and the isolation film; removing the dielectric layer of the peripheral region; and forming a conductive film for a control gate on the entire structure.

### BRIEF DESCRIPTION OF THE DRAWINGS

A more compete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1a to 1d are cross-sectional view illustrating a method of manufacturing a flash memory device according to an embodiment of the invention;

FIG. 2 is a layout diagram illustrating a method of manufacturing a flash memory device according to another embodiment of the invention; and

FIG. 3 is a cross-sectional view illustrating a method of manufacturing a flash memory device according to another embodiment of the invention.

### DETAILED DESCRIPTION OF EMBODIMENTS

In the following detailed description, only certain exemplary embodiments of the invention have been shown and described simply by way of illustration.

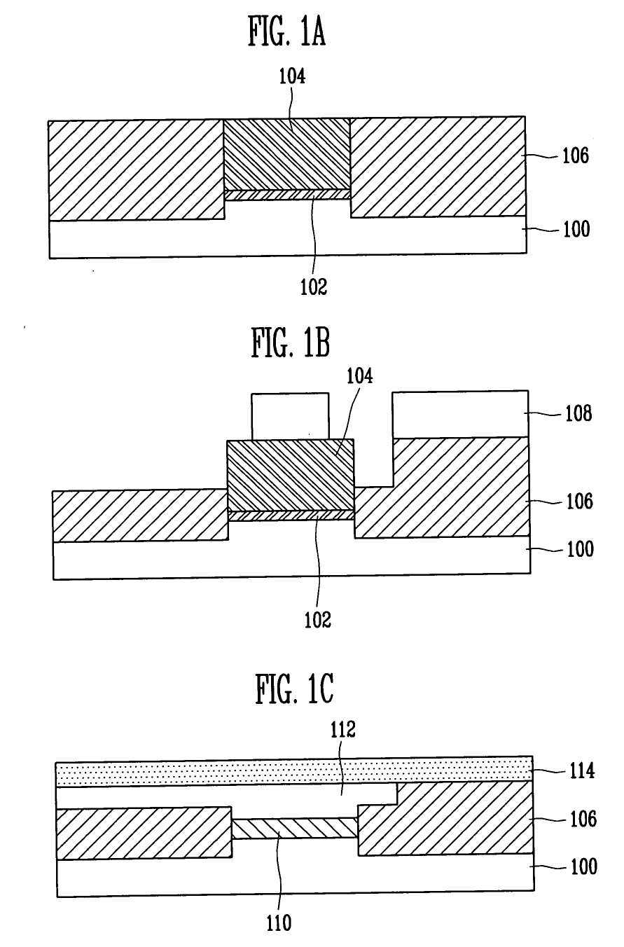

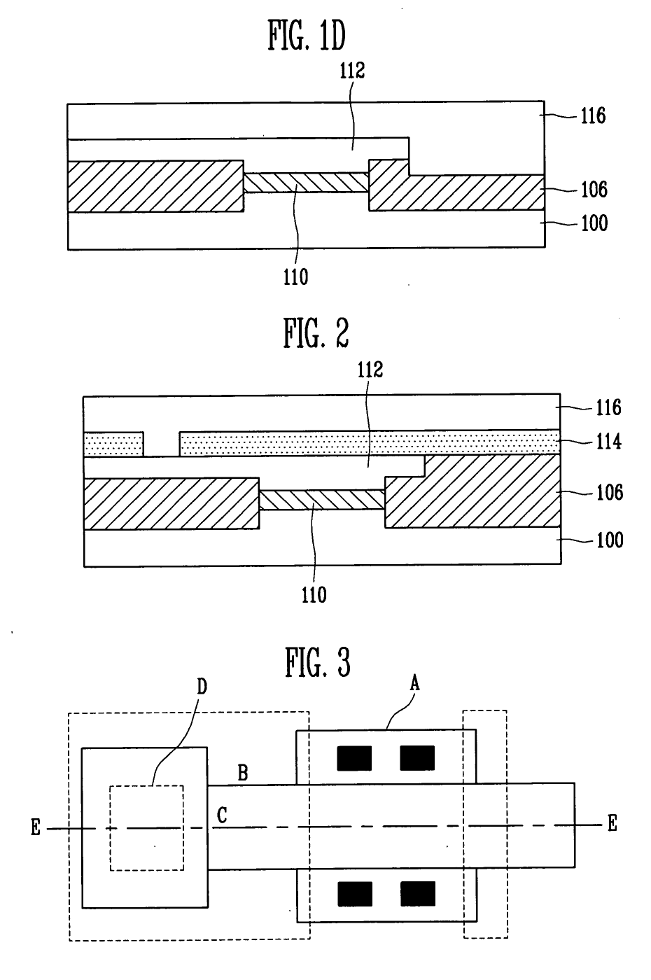

FIGS. 1a to 1d are cross-sectional view illustrating a method of manufacturing a flash memory device according to an embodiment of the invention.

Referring to FIG. 1a, a first oxide film 102 and a hard mask film 104 are deposited on a semiconductor substrate 100 in which a peripheral region is defined. The hard mask film 104, the first oxide film 102, and the semiconductor substrate 100 are etched to form a trench.

After a second oxide film is deposited so that the trench is buried, a polishing process is performed to form an isolation film 106. Chemical mechanical polishing (CMP) may preferably be used as the polishing process.

Referring to FIG. 1b, a photoresist film is formed on the hard mask film 104 and the isolation film 106, and is then patterned by exposure and development processes.

The isolation film 106 is then partially etched by a predetermined depth using the photoresist film pattern 108 as a mask. The isolation film 106 may be etched to have the same height as or a height higher than that of the gate oxide film 1 10 (i.e., a subsequent process step).

Furthermore, the hard mask film 104 exposed from the photoresist film pattern 108 when etching the isolation film 106 is not etched due to the difference in the etch selectivity with the isolation film 106 of the hard mask film 104. Therefore, the photoresist film pattern 108 on the hard mask film 104 may not be formed.

Referring to FIG. 1c, the photoresist film pattern 108 and the hard mask film 104 are stripped. After the first oxide film 102 is stripped, a gate oxide film 110 may be formed. Alternatively, the gate oxide film 110 may be formed to have a predetermined thickness on the first oxide film 102, which is partially etched upon etching of the hard mask film 104. In the illustrated embodiment, after the first oxide film 102 is completely stripped, the gate oxide film 110 is formed again.

A polysilicon layer 112 is deposited on the entire structure so that the portion in which the isolation film 106 has been etched is buried. A polishing process with a predetermined thickness is then performed. CMP is preferably used as the polishing process. The polysilicon layer 112 is formed to extend on the isolation film 106 at the interface of the active region and the isolation film 106 with it preferably having a length of 10 Å to 500 Å. A dielectric layer 114 is formed on the entire structure.

Referring to FIG. 1d, the dielectric layer 114 is stripped in the peripheral region. When the dielectric layer 114 stripped, a portion in which the polysilicon layer 112 is not formed on the isolation film 106 is over etched because the dielectric layer 114 and the isolation film 106 are made of an oxide material.

A conductive film 116 is then formed on the entire structure. In the illustrated embodiment, the conductive film 116 may preferably be formed by depositing a polysilicon layer and a tungsten silicide film and etching the polysilicon layer and the tungsten silicide film.

If the polysilicon layer 112 is formed on the isolation film 106, the isolation film 106 that has been partially wet-etched is over etched when removing the dielectric layer 114. It is thus possible to prevent a thinning phenomenon in which the gate oxide film 110 becomes thin. As a result, a breakdown voltage of the oxide film, which occurs in the gate oxide film 110, can be prevented.

FIG. 2 is a layout diagram illustrating a method of manufacturing a flash memory device according to another embodiment of the invention.

An active region A and a field region B are defined by an isolation film. A gate region C is defined to cross the active region A. A dielectric layer open region D is set at one side of a dielectric layer so that the dielectric layer formed in the cell region and the peripheral region is suitable for the peripheral region. The gate region C and the first polysilicon layer are connected through the dielectric layer open region D.

FIG. 3 is a cross-sectional view of the flash memory device taken along line E-E in FIG. 2. The method of manufacturing the flash memory device according to another embodiment of the invention is described in detail below with reference to FIG. 3.

Another embodiment of the invention has the same process steps as those of the embodiment of the invention described above. In the present embodiment, however, the dielectric layer 114 of the peripheral region is not fully removed, but is partially removed, thus exposing the polysilicon layer 112.

In this case, the thinning phenomenon in which the gate oxide film 110 is thinned is not generated due to the removal of the dielectric layer 114. It is therefore not necessary to extend the polysilicon layer 112 on the isolation film 106. The polysilicon layer 112 extends only on a portion from which the dielectric layer 114 is removed extends. This is for the purpose of applying a bias to the polysilicon layer 112 through the portion from which the dielectric layer 114 has been removed.

As described above, according to the invention, in the peripheral region, the polysilicon layer is formed to extend on the isolation film at the interface of the active region and the isolation film. The isolation film that has been partially wet-etched is over etched when removing the dielectric layer. It is thus possible to prevent the thinning phenomenon in which the gate oxide film is thinned. As a result, the breakdown voltage of the oxide film, which occurs in the gate oxide film, can be prevented. Furthermore, characteristics of transistors can be prevented. In addition, resistance of about several hundreds ohm/square, of the polysilicon layer can be formed.

While the invention has been described in connection with practical exemplary embodiments, the invention is not limited to the disclosed embodiments but to the contrary, is intended to cover various modifications and equivalent arrangements included within the spirit and scope of the appended claims.

What is claimed is:

1. A method of manufacturing a flash memory device, the method comprising the steps of:
forming a first oxide film on a semiconductor substrate in which a peripheral region is defined, and then etching the first oxide film and the semiconductor substrate to form a trench;
forming a second oxide film so that the trench is buried, forming an isolation film;
forming a gate oxide film and a polysilicon layer on the resulting surface;
forming a floating gate electrode by causing the polysilicon layer to have a predetermined thickness;
forming a dielectric layer along the step of the floating gate and the isolation film;
removing the dielectric layer of the peripheral region; and
forming a conductive film for a control gate on the entire structure.

2. The method of claim 1, comprising entirely removing the dielectric layer of the peripheral region.

3. The method of claim 1, comprising partially removing the dielectric layer of the peripheral region.

4. The method of claim 1, comprising forming the second oxide film after fully removing the first oxide film.

5. The method of claim 1, comprising forming the gate oxide film to have the same height as that of the etched portion of the isolation film.

6. The method of claim 1, comprising forming the gate oxide film to have a height lower than that of the etched portion of the isolation film.

7. The method of claim 1, comprising forming the polysilicon layer to extend on the isolation film at the interface of the active region and the isolation film with it having a length of 10 Å to 500 Å.
